(19) United States
(12) Patent Application Publication
(10) Pub. No.: US 2026/0309809 A1
(43) Pub. Date: Oct. 8, 2026

(54) ANGULAR MAGNETIC FIELD SENSOR DEVICE WITH LINEAR OUTPUT RESPONSE

(71) Applicant: Allegro MicroSystems, LLC, Manchester, NH (US)

(72) Inventors: Santiago Serrano-Guisan, San Jose, CA (US); Anuraag Mohan, Fremont, CA (US)

(73) Assignee: Allegro MicroSystems, LLC, Manchester, NH (US)

(21) Appl. No.: 19/173,186

(22) Filed: Apr. 8, 2025

(51) Int. Cl. G01R 33/00; G01R 33/09

(52) U.S. Cl. CPC G01R 33/0029; G01R 33/098

(57) ABSTRACT

The invention relates to a magnetic angular sensor device configured to measure the orientation of the external applied magnetic field. Example embodiments of the disclosure provide methods and apparatus to generate an output voltage that is linear with respect to the orientation of the external applied magnetic field with angular magnetic field ranges up to ±90°.

### BACKGROUND

Magnetic sensors have many consumer, industrial and automotive applications. Current sensing, positioning, proximity detection, biometric sensing are some examples. Sensor technologies using magnetic tunnel junctions (MTJs) based on tunnel magnetoresistance (TMR) effect excel among rival technologies based on anisotropic magnetoresistance (AMR) effect, giant magnetoresistance (GMR) effect and Hall effect, thanks to their higher sensitivity and signal-to-noise ratio (SNR), lower temperature dependence, better long-term stability, and generally smaller die size.

### SUMMARY

Example embodiments of the disclosure provide methods and apparatus for a magnetic sensor device configured to measure a two-dimensional orientation angle of an external magnetic field and to generate a corresponding device output voltage that is linear with respect to the orientation of the external magnetic field. In embodiments, a magnetic sensor device comprises at least a sine magnetic sensor configured to generate a sine output voltage and a cosine magnetic sensor configured to generate a cosine output voltage, where each of the sine and cosine magnetic sensors comprise a plurality of MTJ elements.

Example embodiments of the disclosure are directed to magnetic angular sensor devices configured to measure the orientation of the external applied magnetic field. Example embodiments of the disclosure provide methods and apparatus to generate an output voltage that is linear with respect to the orientation of the external applied magnetic field with angular magnetic field ranges up to ±90° having a minimal linearity error and angular error.

Magnetic sensors can show unidirectional sensitivity (so called 1D magnetic sensors) or bidirectional sensitivity (so called 2D magnetic sensors or angular magnetic sensors). Ideally 1D sensors should show a linear magnetic response, and angular magnetic sensors should show a sinusoidal response with respect to an external magnetic field orientation.

A TMR-based magnetic sensor typically comprises a plurality of magnetic tunnel junction (MTJs) elements as shown in FIG. 1, for example. Each MTJ element 20 typically comprises a tunnel barrier layer 22 sandwiched between a ferromagnetic reference layer 21 and a ferromagnetic sense layer 23. The reference layer 21 has a fixed reference magnetization 27. The sense layer 23 has a sense layer magnetization 25 that can be oriented along the direction of the external magnetic field 60.

Typically, an angular magnetic field sensor comprises two full bridge magnetic sensing elements in order to ensure an unambiguous determination of the orientation of the external magnetic field 60. The first full bridge magnetic sensing element generates a sine output voltage V_{SIN} following a sine signal and the second full bridge magnetic sensing element generates a cosine output voltage V_{COS} following a cosine signal (see, e.g., FIG. 2B). The cosine output voltage V_{COS} and the sine output voltage V_{SIN} can respectively be described by:

$$\begin{matrix}{V}_{COS} = A \cdot cos θ \cdot {V}_{dd} , \\ {V}_{SIN} = A \cdot sin θ \cdot {V}_{dd} .\end{matrix}$$

where A is the amplitude of the output voltage signal V_{SIN}, V_{COS} and V_{dd} is the bias voltage applied to the magnetic sensing element 2. The orientation θ of the external magnetic field 60 is then determined by the arc tangent of the ratio between the sine output voltage V_{SIN} and the cosine output voltage V_{COS}:

$${θ}_{m} = arctan ( {V}_{SIN} / {V}_{COS} ) .$$

The determination of the orientation of the external magnetic field 60 requires the use of analog-digital-converters (ADC), microcontrollers (MCU) and/or the implementation of different iterative algorithm schemes (such as CORDIC schemes, for instance), impacting on the response speed and/or power consumption of the angular magnetic sensor. In order to increase the response speed, extensive CMOS design with very fast internal clocks can be used. However, this leads to a large die size.

Therefore, for ultra-fast angular sensor applications, it is desirable to provide an angular magnetic sensor capable of generating an output voltage response that is linear with respect to the orientation of the external magnetic field. So far, only for small angular ranges (θ≤±10°) linear responses are obtained.

The present disclosure provides a magnetic angular sensor device to measure the orientation of the external applied magnetic field and configured to generate an output voltage that is linear with respect to the orientation of the external applied magnetic field with angular magnetic field ranges up to ±90° having a minimal linearity error and angular error.

In one aspect, an angular magnetic field sensor device for measuring the orientation of an external magnetic field comprises: at least a sine magnetic sensor, comprising a plurality of tunnel magnetoresistance (TMR) elements, arranged in a full-bridge configuration and configured to provide a sine output voltage V_{SIN} defined as V_{SIN}=A·sin θ·V_{dd}, where A is the amplitude parameter depending on a TMR ratio of the TMR elements, V_{dd} is an input voltage of the magnetic sensor and θ is an orientation of the external magnetic field; an analog circuit comprising at least one tunnel magnetoresistance (TMR) element configured to generate a circuit output voltage V_{out_ac} depending on the orientation of the external magnetics field θ.

A device can further include one or more of the following features: the circuit output voltage V_{out_ac} is defined as:

$${V}_{out \_ ac} = \frac{1}{( C + A \cdot cos θ )} \cdot {V}_{in \_ ac} ,$$

where C is an offset voltage generated by the analog circuit and V_{in_ac} is an input voltage of the analog circuit, the sine magnetic sensor and the analog circuit are electrically connected so the output voltage generated by the angular magnetic field sensor device is proportional to:

$${V}_{out} = \frac{A \cdot sin θ}{( C + A \cdot cos θ )} ,$$

1<C/A≤2.5, C/A=1.7±0.2, the analog circuit is driven by the output voltage of the sine magnetic field sensor, the sine magnetic field sensor is driven by the output voltage of the analog circuit, the output voltage of the device has a linearity error <0.5% and/or angular error <1 deg for angular magnetic field ranges up to ±90°, an additional analog circuit comprising at least one tunnel magnetoresistance (TMR) element configured to generate a circuit output voltage V_{out2_ac} depending on the orientation of the external magnetics field θ:

$${V}_{out 2 \_ ac} = \frac{1}{( {C}_{2} + A \cdot cos θ )} \cdot {V}_{in 2\_ ac} ,$$

where C₂ is an offset voltage generated by the additional analog circuit and V_{in2_ac} is the input voltage of the additional analog circuit, the sine magnetic sensor is electrically connected to the analog circuit, the sine magnetic sensor is electrically connected to the additional analog circuit, the output voltage generated by the angular magnetic field sensor device is proportional to the addition of output voltages of the analog circuit and the additional analog circuit, a voltage amplifier with gain k1 coupled to an output of the analog circuit, a voltage amplifier with gain k2 coupled to an output of the additional analog circuit, a summing amplifier to add the output voltages of the analog circuit and the additional analog circuit, 1<C/A≤10 and 1<C₂/A≤10, the device output voltage has a linearity error <0.5% and/or angular error <1 deg for angular magnetic field ranges up to ±90°, the sine magnetic sensor is electrically connected to the analog circuit of the angular magnetic field sensor device, and wherein the output voltage generated by the angular magnetic field sensor device is proportional to the addition of the output voltage of the analog circuit and the output voltage of the sine magnetic sensor, a summing amplifier to add the output voltage of the analog circuit and the output voltage of the sine magnetic sensor, and/or the device output voltage shows a linearity error <0.5% and/or angular error <1 deg for angular magnetic field ranges up to ±90°.

In one aspect, an angular magnetic field sensor device for measuring the orientation of an external magnetic field, comprises: at least a sine magnetic sensor, comprising a plurality of tunnel magnetoresistance (TMR) elements, arranged in a full-bridge configuration and configured to provide a sine output voltage V_{SIN} defined as V_{SIN}=A·sin θ·V_{dd}, where A is the amplitude parameter depending on a TMR ratio of the TMR elements, V_{dd} is an input voltage of the magnetic sensor and θ is an orientation of the external magnetic field; an analog circuit comprising at least one AC tunnel magnetoresistance (TMR) element configured to generate a circuit output voltage V_{out_ac} depending on the orientation of the external magnetics field θ.

The device can further include one or more of the following features: the circuit output voltage V_{out_ac} is defined as:

$${V}_{out \_ ac} = \frac{1}{( C + A \cdot cos θ )} \cdot {V}_{in \_ ac}$$

where C is an offset voltage generated by the analog circuit and V_{in_ac} is an input voltage of the analog circuit, the sine magnetic sensor and the analog circuit are electrically connected so the output voltage generated by the angular magnetic field sensor device is proportional to:

$${V}_{out} = \frac{A \cdot sin θ}{( C + A \cdot cos θ )} ,$$

1<C/A≤2.5, C/A=1.7±0.2, the analog circuit is driven by the output voltage of the sine magnetic field sensor, the sine magnetic field sensor is driven by the output voltage of the analog circuit, an additional analog circuit comprising at least one tunnel magnetoresistance (TMR) element configured to generate a circuit output voltage V_{out2_ac} depending on the orientation of the external magnetics field θ:

$${V}_{out 2 \_ ac} = \frac{1}{( {C}_{2} + A \cdot cos θ )} \cdot {V}_{in 2\_ ac}$$

wherein C₂ is an offset voltage generated by the additional analog circuit and V_{in2_ac} is the input voltage of the additional analog circuit, the sine magnetic sensor is electrically connected to the analog circuit, the sine magnetic sensor is electrically connected to the additional analog circuit, the output voltage generated by the angular magnetic field sensor device is proportional to the addition of output voltages of the analog circuit and the additional analog circuit, a voltage amplifier with gain k1 coupled to an output of the analog circuit, a voltage amplifier with gain k2 coupled to an output of the additional analog circuit, a summing amplifier to add the output voltages of the analog circuit and the additional analog circuit, a differential amplifier to subtract the output voltages of the analog circuit and the additional analog circuit, 1<C/A≤10 and 1<C₂/A≤10, the sine magnetic sensor is electrically connected to the analog circuit of the angular magnetic field sensor device, and wherein the output voltage generated by the angular magnetic field sensor device is proportional to the addition of the output voltage of the analog circuit and the output voltage of the sine magnetic sensor, a summing amplifier to add the output voltage of the analog circuit and the output voltage of the sine magnetic sensor, the device output voltage shows a linearity error <0.5% and/or angular error <1 deg for angular magnetic field ranges up to ±90°, and/or the TMR elements show a TMR ratio >120%.

### BRIEF DESCRIPTION OF THE DRAWINGS

The foregoing features may be more fully understood from the following description of the drawings. The drawings aid in explaining and understanding the disclosed technology. Since it is often impractical or impossible to illustrate and describe every possible embodiment, the provided figures depict one or more illustrative embodiments. Accordingly, the figures are not intended to limit the scope of the broad concepts, systems and techniques described herein. Like numbers in the figures denote like elements.

FIG. 1 illustrates a TMR-based angular magnetic sensor comprising an array of MTJ elements;

FIG. 2A shows a plurality of MTJ elements arranged in a full bridge circuit;

FIG. 2B shows output voltages generated by a magnetic sensing element;

FIG. 3 shows an analog angular magnetic sensor device, according to an embodiment;

FIG. 4 shows the analog angular magnetic sensor device, according to another embodiment;

FIG. 5A is a graphical representation of a C/A ratio for an angular magnetic sensor in accordance with example embodiments of the disclosure;

FIG. 5B shows these two different dVₒᵤₜ/dθ behaviours: for C/A=2, dVₒᵤₜ/dθ is maximum at θ=0° and it smoothly decreases when moving from 0°; for C/A=1.2, dVₒᵤₜ/dθ shows a relative minimum at θ=0° and it smoothly increases when moving from 0°;

FIG. 5C shows that an appropriate C/A ratio will be dependent on the targeted angle range and linearity error;

FIG. 6A shows that, for a ratio C/A of about 1.7, the device output voltage Vₒᵤₜ varies linearly with respect to the angle θ of the external magnetic field; FIG. 6B shows linearity error when the angle of the external magnetic field is varied between −90° and 90° and, FIG. 6C shows angular error (AE) of about 0.26° when the angle of the external magnetic field is varied between −90° and 90°;

FIG. 7A shows another embodiment of an angular magnetic sensor device having enhanced linearity in accordance with example embodiments of the disclosure;

FIG. 7B shows a further alternative embodiment in which an additional analog circuit is added to the circuit of FIG. 7A;

FIG. 7C shows a further alternative embodiment in which an additional analog is added to the circuit of FIG. 7A;

FIG. 8 shows a further alternative embodiment of an angular magnetic sensor device having enhanced linearity in accordance with example embodiments of the disclosure;

FIG. 9A shows an example of an angular magnetic field sensor device similar to the circuit of FIG. 3 without an offset circuit;

FIG. 9B shows a variant of the angular magnetic field sensor device of FIG. 9A with a fully differential operational amplifier and a differential amplifier;

FIG. 10 shows an example circuit of an alternative embodiment of an angular magnetic sensor device comprising a sine full-bridge magnetic sensor, and a single TMR element R₂ following a cos− response;

FIG. 11 shows a further alternative embodiment of an angular magnetic field device of FIG. 10 with a fully differential operational amplifier, a differential amplifier, and comprising two TMR elements R₃ and R₄ following a cos− response;

FIGS. 12A and 12B show generalized block diagrams of respective angular magnetic sensor devices generating an output voltage response proportional to Eq. 4a and able to provide a linear output voltage with respect to the orientation of the external magnetic field θ;

FIG. 13A show responses of a further alternative embodiment of an angular magnetic field sensor device for which the device output voltage Vₒᵤₜ varies linearly with respect to the angle θ of the external magnetic field 60 when the angle of the external magnetic field 60 is varied between −90° and 90° with a linearity error smaller than about 0.03%, as shown in FIG. 13B, and an AE of <0.04° is obtained as shown in FIG. 13C;

FIGS. 14A-D show different examples of optimum conditions of C₁/A ratio, C₂/A ratio and k parameter for linearity errors <0.1%;

FIG. 15 shows a generalized block diagram of an angular magnetic field sensor device generating an output voltage described by Eq. 4b;

FIG. 16A show responses of a further alternative embodiment of an angular magnetic field sensor device for which the device output voltage Vₒᵤₜ varies linearly with respect to the angle θ of the external magnetic field when the angle of the external magnetic field is varied between −90° and 90° with a linearity error smaller than about 0.03%, as shown in FIG. 16B, and an AE of <0.04° is obtained as shown in FIG. 16C; and

FIG. 17 shows an angular magnetic field sensor device generating an output voltage described by Eq. 4c.

### DETAILED DESCRIPTION

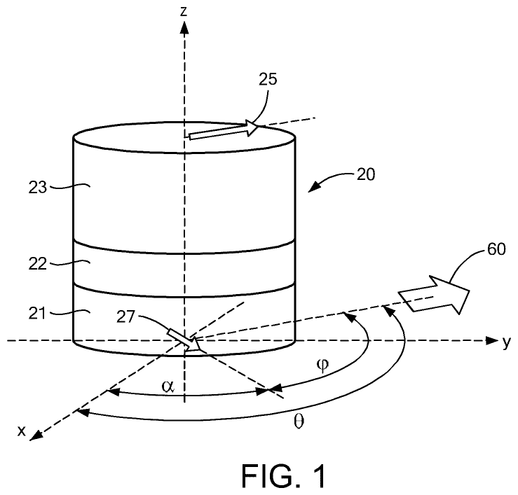

FIG. 1 shows an example TMR-based angular magnetic sensor comprising an array of MTJ elements 20. Each MTJ element 20 typically comprises a reference layer 21 having a fixed reference magnetization 27, a sense layer 23 having a sense magnetization 27 that can be oriented along the direction of the external magnetic field 60 and a tunnel barrier layer 22 between the pinned and sense layers 21, 23. The resistance R of each MTJ element is dependent on the relative orientation between the sense magnetization 25 and the reference magnetization 27 due to the TMR effect. Thus, by changing the orientation of the external magnetic field 60 a variation of the output voltage is obtained.

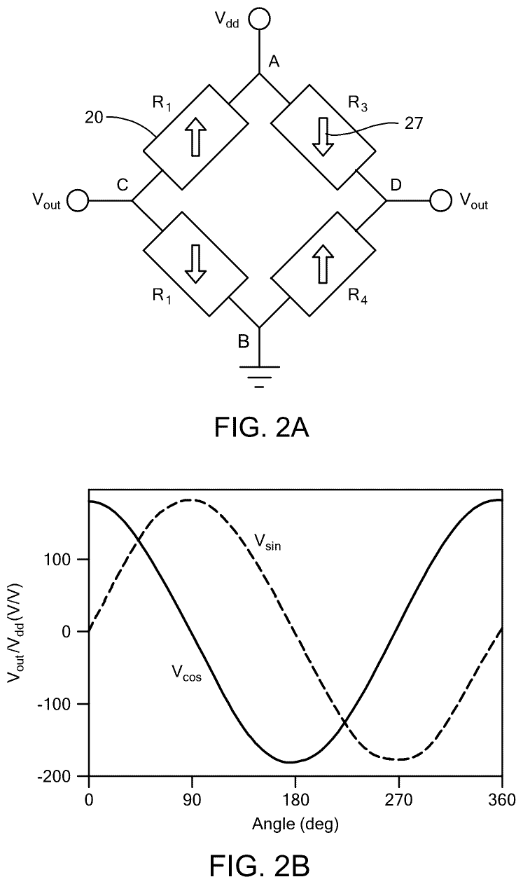

FIG. 2A shows a 2D magnetic sensing device comprising a plurality of MTJ elements 20 arranged in a Wheatstone bridge circuit (also commonly called full bridge circuit). Each branch of the Wheatstone bridge 2 comprises one or a plurality of MTJ elements 20 connected in series and/or parallel. Namely, R₁, R₂, R₃ and R₄ are the resistances of each branch of the Wheatstone bridge 2 and V_{dd} is the applied bias voltage. Typically, the reference magnetization 27 can have a first orientation for two diagonal branches (for example branches R₁ and R₄) and a second orientation opposed to the first orientation for the two other diagonal branches (for example branches R₂ and R₃). Typically, a 2D magnetic sensing device comprises two Wheatstone bridges, where the reference magnetization 27 of each Wheatstone bridge are orthogonal to each other. In this configuration, two output voltages (one for each Wheatstone bridge) V_{SIN} and V_{COS} are generated by the 2D magnetic sensing element 2, where V_{COS} follows a cosine (COS) signal and V_{SIN} follows a sine (SIN) signal, as shown in FIG. 2B, and described by:

$${V}_{COS} = A \cdot cos θ \cdot {V}_{dd} , and \qquad ( Eq . 1 a )$$

$${V}_{SIN} = A \cdot sin θ \cdot {V}_{dd} . \qquad ( Eq . 1 b )$$

where A is the signal amplitude. V_{COS} & V_{SIN} can also be expressed as:

$${V}_{COS} = {v}_{COS} \cdot {V}_{dd} \qquad ( Eq . 1 c )$$

$${V}_{SIN} = {v}_{SIN} \cdot {V}_{dd} . \qquad ( Eq . 1 d )$$

Where v_{COS} & v_{SIN} express the normalized output voltage of the COS full-bridge sensor and the SIN full-bridge sensor respectively and following Eq. 1e, 1f:

$${v}_{COS} = A \cdot cos θ \qquad ( Eq . 1 e )$$

$${v}_{SIN} = A \cdot sin θ . \qquad ( Eq . 1 f )$$

The measured orientation θₘₑₐₛ of the external magnetic field 60 is then determined by the arc tangent of the ratio between the sine output voltage V_{SIN} and the cosine output voltage V_{COS}:

$${θ}_{m e a s} = arctan ( {V}_{SIN} / {V}_{COS} ) \qquad ( Eq . 2 )$$

The angular error (AE) can be determined by:

$$A E = {θ}_{m e a s} - θ \qquad ( Eq . 3 )$$

The determination of the measured orientation θₘₑₐₛ by using equation 2 may be complicated since tan θ diverges at θ=±90°. It is therefore challenging to develop a TAN based analog sensor for ranges up to ±90°.

In example embodiments of the disclosure, a magnetic sensor device comprises at least a sine magnetic sensor configured to generate an output voltage v_{SIN} proportional to a sine function with respect to the orientation of the external applied magnetic field and a cosine magnetic sensor configured to generate an output voltage v_{COS} proportional to a cosine function with respect to the orientation of the external applied magnetic field, wherein each of the sine and cosine magnetic sensors comprising a plurality of MTJ elements. The magnetic sensor device can include an analog circuit configured to generate an output voltage and electrically connected to the magnetic sensors such as that the magnetic sensor device generates a device output voltage proportional to one of the following responses:

$${V}_{out} = \frac{{v}_{SIN}}{{v}_{COS} + {C}_{1}} = \frac{A \cdot sin θ}{A \cdot cos θ + {C}_{1}} \qquad ( Eq . 4 a )$$

$${V}_{out} = \frac{{v}_{SIN}}{{v}_{COS} + {C}_{1}} + \frac{k \cdot {v}_{SIN}}{{v}_{COS} + {C}_{2}} = \frac{A \cdot sin θ}{A \cdot cos θ + {C}_{1}} + k \cdot \frac{A \cdot sin θ}{A \cdot cos θ + {C}_{2}} \qquad ( Eq . 4 b )$$

$${V}_{out} = {v}_{SIN} + k \cdot \frac{{v}_{SIN}}{{v}_{COS} + {C}_{1}} = A \cdot sin θ + k \cdot \frac{A \cdot sin θ}{A \cdot cos θ + {C}_{1}} \qquad ( Eq . 4 c )$$

where C₁ and C₂ are offset constants described more fully below and k is an optional constant.

Analog determination of the measured orientation θₘₑₐₛ is usually considered for applications involving small angle ranges (typically θ≤10°) such that the sinusoidal output of the angular magnetic sensor can be approximated to a linear function with respect to the measured orientation θₘₑₐₛ. Current analog angular magnetic sensors do not allow fast determination of the measured orientation θₘₑₐₛ unless for applications involving small angle ranges (typically θ≤10°).

In example embodiments of the disclosure, an analog angular magnetic sensor device (thereafter called “magnetic sensor device”) is configured to measure a two-dimensional (2D) orientation angle of an external magnetic field and to generate a corresponding device output voltage. The magnetic sensor device includes a sine full-bridge magnetic sensor configured to generate a sine output voltage and a cosine full-bridge magnetic sensor configured to generate a cosine output voltage. Each of the sine and cosine magnetic sensors comprise a plurality of MTJ elements. The magnetic sensor device may further comprise an analog circuit having at least an analog offsetting circuit configured to add an offset voltage to the cosine output voltage, for example, an analog inverting circuit configured to invert the output voltage generated by the analog offsetting circuit, and an analog circuit divider to generate a device output voltage Vₒᵤₜ that will follow Eq. 4a.

Example embodiments of the disclosure provide magnetic sensor device that generate device output voltages have enhanced linearity as compared to known devices. In one particular embodiment, an analog offsetting circuit can adjust the offset voltage such that the device output voltage Vₒᵤₜ is linear with respect to the orientation angle of the external magnetic field θ and can be measured between −90° and ±90° with a linearity error smaller than 0.15%.

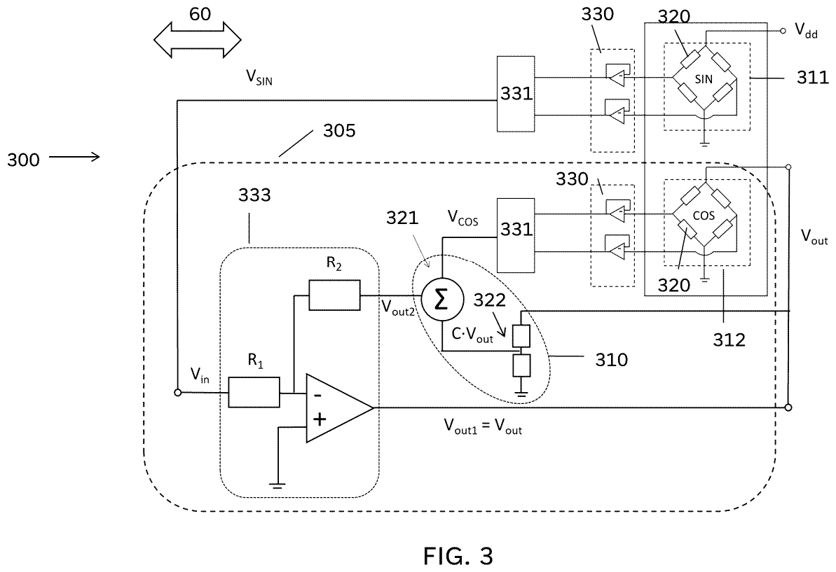

FIG. 3 shows an example of an angular magnetic sensor device 300 for generating a device output voltage with enhanced linearity in accordance with illustrative embodiments of the disclosure. The magnetic sensor device 300 comprises a sine full-bridge magnetic sensor 311 configured to generate a differential output voltage that is a sine output voltage V_{SIN} and is proportional to its bias voltage V_{dd} (as described by Eq. 1b). The sine output voltage V_{SIN} follows a sine function with respect to the external magnetic field orientation. Both half-branch output voltages of the sine full-bridge magnetic sensor 311 are electrically connected to an amplifier buffer 330 and to a differential amplifier 331.

The magnetic sensor device 300 further includes an analog circuit 305 with one input voltage terminal (3A) and one output voltage terminal (3C). The analog circuit 305 further comprises a cosine full-bridge magnetic sensor 312 configured to generate a differential output voltage that is a cosine output voltage V_{COS} and is proportional to its bias voltage. The cosine output voltage V_{COS} follows a cosine function with respect to the external magnetic field orientation. Both half-branch output voltages of the cos full-bridge magnetic sensor 312 are electrically connected to an amplifier buffer 330 and to a differential amplifier 331. The output voltage Vₒᵤₜ of the magnetic sensor device 300 is generated by the output voltage terminal 3C of the analog circuit 305. Additionally, the sine output voltage V_{SIN} of the sine full-bridge magnetic sensor 311 is connected to the input terminal 3A of the analog circuit 305 . . . . Analog circuit 305 comprises an analog offsetting circuit 310 and an analog inverting operational amplifier circuit 333. The role of the analog offsetting circuit 310 is to add an additional offset voltage to the cosine output voltage V_{COS} so the output voltage of the analog offsetting circuit 310 is Vₒᵤₜ₂=V_{COS}+C. Vₒᵤₜ. In one embodiment, the analog offsetting circuit 310 comprises a voltage divider 322 generating an output voltage proportional to the output voltage of the magnetic sensor device 300 and a summing amplifier 321. The output voltage of the summing amplifier 321 corresponds to the output voltage of the analog offsetting circuit 310. The analog offsetting circuit 310 is inputted by the cosine output voltage V_{COS} of the cos full-bridge magnetic sensor 312 and by the output voltage Vₒᵤₜ of the magnetic sensor device 300.

The analog inverting operational amplifier circuit 333 comprises an operational amplifier 313, a first resistance R₁ and a second resistance R₂ where the output voltage of the op-amp 313 is used to bias the cosine full-bridge magnetic sensor 312 and it is also connected to the voltage divider 322 of the analog offsetting circuit 310. The output voltage of the op-amp 313 is generating the output voltage of the analog circuit 305 and corresponds to the output voltage of the magnetic sensor device 300. The output terminal of the analog offsetting circuit 310 is connected to the inverting input terminal of the op-amp 313 through the second resistance R₂ to provide a feedback loop of the inverting op-amp 313. The sine output voltage V_{SIN} generated by the differential amplifier 331 is also connected to the inverting input terminal of the op-amp 313 through the first resistance R₁. The non-inverting terminal of the op-amp 313 is connected to the ground in the illustrated embodiment.

As a consequence of this configuration:

$${V}_{SIN} / {R}_{1} = - {V}_{out 2} / {R}_{2} \qquad ( Eq . 5 a )$$

$$or :$$

$${V}_{SIN} \cdot {R}_{2} = - {R}_{1} \cdot ( {V}_{COS} + C \cdot {V}_{out} ) = - {R}_{1} \cdot ( A \cdot cos θ + C ) \cdot {V}_{out} \qquad ( Eq . 5 b )$$

Hence, the output voltage of the magnetic sensor deice 300 can be expressed as:

$${V}_{out} = - \frac{{R}_{2}}{{R}_{1}} \cdot \frac{A \cdot sin θ}{( A \cdot cos θ + C )} \cdot {V}_{dd} \qquad ( Eq . 5 c )$$

and being proportional to Eq. 4a.

In an embodiment, the sine and cosine magnetic sensors 311, 312 are full bridge magnetic sensors. In other words, each of the sine and cosine magnetic sensors 311, 312 comprises a plurality of MTJ elements 320 arranged in a full bridge circuit, such as a Wheatstone bridge circuit. For example, the plurality of MTJ elements 320 can be arranged in a full bridge circuit as shown in FIG. 2A. Each MTJ element 320, as shown in FIG. 1, can comprise tunnel barrier layer 22 sandwiched between a ferromagnetic reference layer 21 and a ferromagnetic sense layer 23. The reference layer 21 has a fixed reference magnetization 27. The sense layer 23 has a sense magnetization 25 that can be oriented in an external magnetic field 60.

In one aspect, a bias voltage V_{dd} is applied between the bias input (see for example nodes A and B, see FIG. 2A) and a differential output voltage is generated between the differential output (see for example the nodes C and D, see FIG. 2A), of the sine and cosine full-bridge magnetic sensors 311, 312. In one aspect, the reference magnetization 27 can have a first orientation for two diagonal branches and a second orientation opposed to the first orientation for the two other diagonal branches. In the case, the reference magnetization 27 in the sine magnetic sensor is oriented orthogonally with respect to the cosine magnetic sensor 312.

In one aspect, the output of each of the sine and cosine magnetic sensors 311, 312 can be further electrically connected to an amplifier buffer 330 (voltage follower) and to a differential amplifier 331.

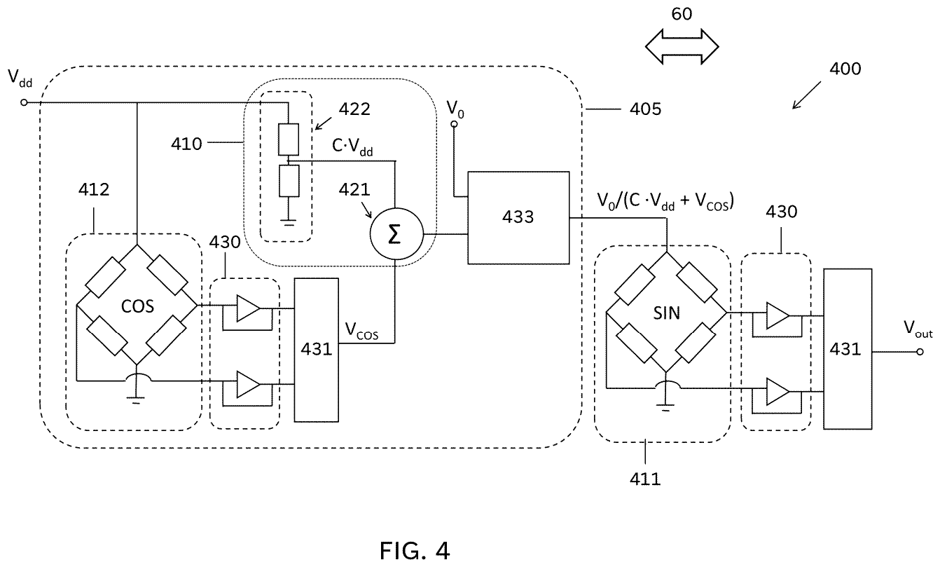

FIG. 4 shows a magnetic sensor device 400, according to another embodiment. The magnetic sensor device 400 comprises a sine magnetic sensor 411 configured to generate a sine output voltage V_{SIN}.

The magnetic sensor device 400 further comprises an analog circuit 405 comprising a cosine magnetic sensor 412 configured to generate a cosine output voltage V_{COS}, an analog circuit divider 433 and an analog offsetting circuit 410. In the illustrated embodiment, the output of each of the sine and cosine magnetic sensors 411, 412 can be further electrically connected to amplifier buffer 430 and to a differential amplifier 431. Each of the sine and cosine magnetic sensors 411, 412 comprises a plurality of MTJ elements arranged in a full bridge circuit, as described above.

In an example embodiment, the analog offsetting circuit 410 comprises a summing amplifier 421 connected to the cosine output voltage V_{COS} of the cosine magnetic sensor 412, via the amplifier buffer 430 and the differential amplifier 431. The analog offsetting circuit 410 further comprises a voltage divider 422. The voltage divider 422 is inputted by the bias voltage V_{dd} applied to the cosine magnetic sensor 412 such as to generate an offset output voltage C Vₒᵤₜ. The summing amplifier 421 combines the cosine output voltage V_{COS} and the offset output voltage C Vₒᵤₜ and inputs the combination into an input of the analog circuit divider 433. Another input of the analog circuit divider 433 is inputted by a divider input voltage V₀, such that the analog circuit divider 433 generates a first output voltage Vₒᵤₜ₁ described by equation 6:

$${V}_{out 1} = {V}_{0} / ( C \cdot {V}_{dd} + {V}_{COS} ) . \qquad ( Eq . 6 a )$$

Thus, the magnetic sensor device 400 of FIG. 4 generates an output voltage Vₒᵤₜ proportional to Eq. 6b.

$${V}_{out} = \frac{A \cdot sin θ}{( A \cdot cos θ + C )} \cdot {V}_{dd} \qquad ( Eq . 6 b )$$

which is proportional to Eq. 4a.

In some embodiments (not shown), the output voltage of the sine magnetic sensor 411 can be used as a divider input voltage V₀. Similarly, in this configuration, the output voltage generated by the magnetic sensor device 400, will be also described by Eq. 6b.

It is important to note that when the offset output voltage is zero (C=0), the output voltage Vₒᵤₜ follows a tangent function:

$${V}_{out} = tan θ \cdot {V}_{dd} \qquad ( Eq . 7 a )$$

which diverges when the magnetic field orientation θ of the external magnetic field is ±90°, making this device unpractical for angular magnetic field detection at large angle ranges. As a matter of fact, the device output voltage Vₒᵤₜ always diverges if a ratio 0≤C/A≤1. However, the magnetic field orientation θ at which Vₒᵤₜ does diverge increases from ±90° (for C=0) to ±180° (for C/A=1). Indeed, for a ratio C/A=1, the device output voltage Vₒᵤₜ follows:

$${V}_{out} = tan ( θ / 2 ) \cdot {V}_{dd} , \qquad ( Eq . 7 b )$$

diverging when the magnetic field orientation θ of the external magnetic field is ±180°.

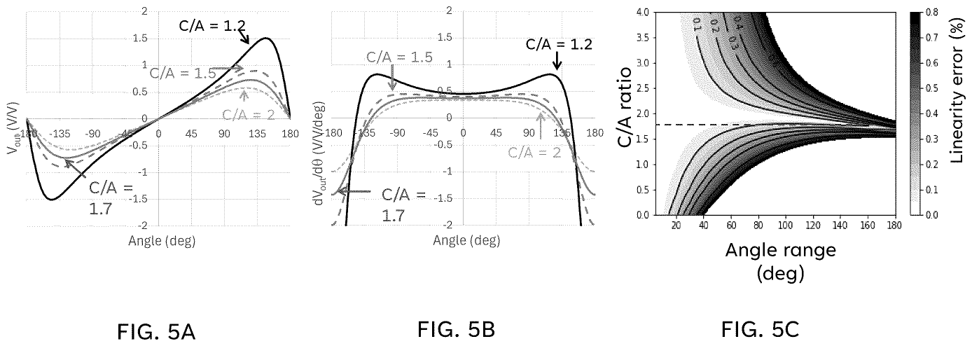

Only for C/A >1, the device output voltage Vₒᵤₜ is continuous with no divergence and showing a periodicity of 360° when the angle θ of the external magnetic field 60 is varied between −180° and 180°. Note that these properties are essential for an angular magnetic field sensor. FIG. 5A shows the device output voltage response Vₒᵤₜ described by Eq. 6b for C/A ratios of 1.2, 1.5, 1.7 and 2.0.

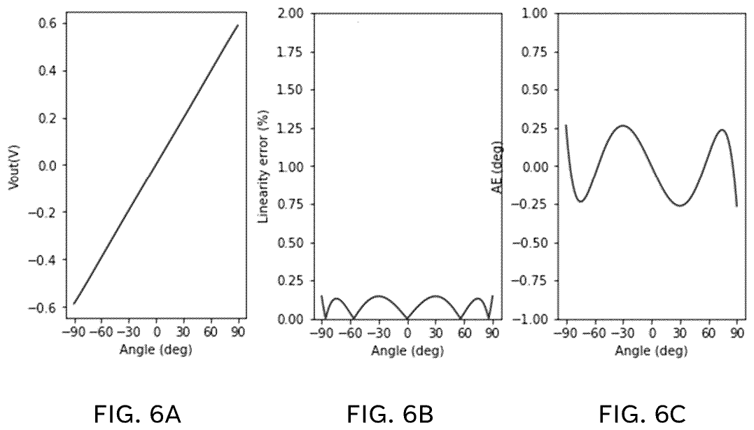

As can best be seen in FIG. 6A, for a ratio C/A of about 1.7, the device output voltage Vₒᵤₜ varies linearly with respect to the angle θ of the external magnetic field 60 with a linearity error smaller than about 0.15%, as shown in FIG. 6B, and an AE of about 0.26° as shown in FIG. 6C when the angle of the external magnetic field 60 is varied between −90° and 90°.

This unexpected linearity performance can be explained by the particular properties of Eq. 6b with respect to angle θ for different C/A ratios. For C/A >>1, we can expect Vₒᵤₜ be similar to a sine function with a relative maximum V_{outMax} and a relative minimum V_{outMin}=−V_{outMax} at angles close to ±90° and −90°. At such conditions the amplitude of dVₒᵤₜ/dθ continually decreases with θ for an angle range of [−90°, 90°] with respect to its initial value at 0°. Conversely, for C/A=1, Vₒᵤₜ can be expressed by Eq. 7b, and diverges at ±180°. This implies that, at such conditions, the amplitude of dVₒᵤₜ/dθ continually increases with θ for an angle range of [−90°, 90°] with respect to its initial value at 0°. These two opposite behaviours of dVₒᵤₜ/dθ for different C/A ratios indicate that it might be possible to determine a specific range of C/A ratio where dVₒᵤₜ/dθ is almost constant, leading to a Vₒᵤₜ linear with respect to angle θ.

FIG. 5B shows these two different dVₒᵤₜ/dθ behaviours: for C/A=2, dVₒᵤₜ/dθ is maximum at θ=0° and it smoothly decreases when moving from 0°; for C/A=1.2, dVₒᵤₜ/dθ shows a relative minimum at θ=0° and it smoothly increases when moving from 0°. However, for C/A=1.7 a relatively stable dVₒᵤₜ/dθ over an angle range of [−90°, 90°] is obtained, leading to a high linear output voltage Vₒᵤₜ as shown in FIG. 5A & FIG. 6

This linearity performance with respect to C/A ratio holds for all embodiments with an output voltage response Vₒᵤₜ proportional to Eq. 4a. It is also important to note that the appropriate C/A ratio will be dependent on the targeted angle range and linearity error as shown in FIG. 5c. Thus, for an angle range of [−90°, 90°] (or 180°) an optimum linearity error of ~0.15% is obtained for a C/A=1.7. However, for an angle range of [−30°, 30°] similar linearity errors are obtained for 1.7<C/A<2.1.

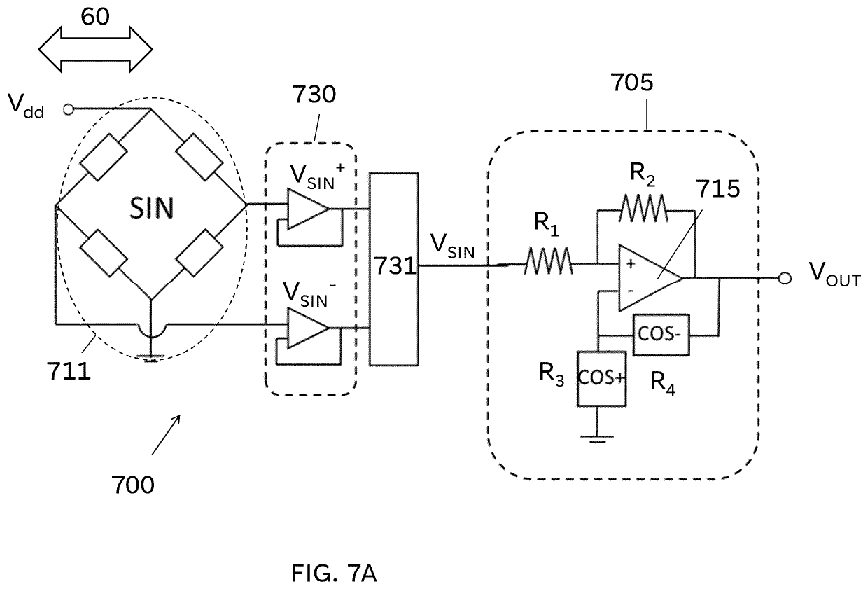

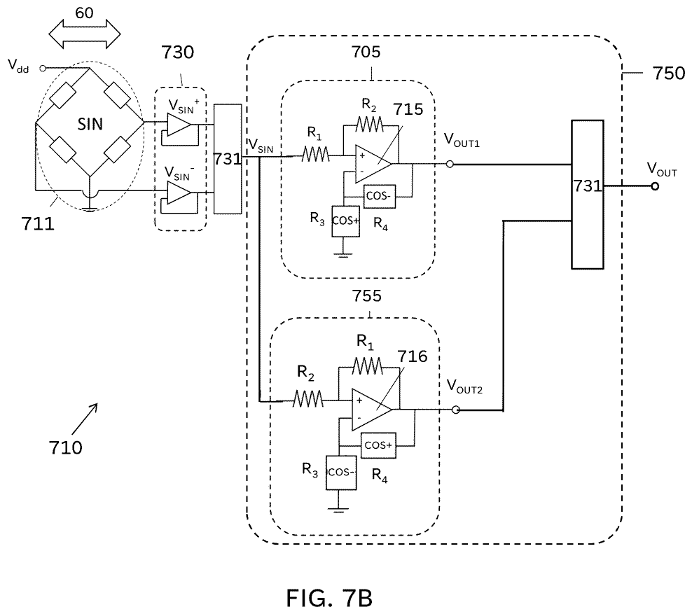

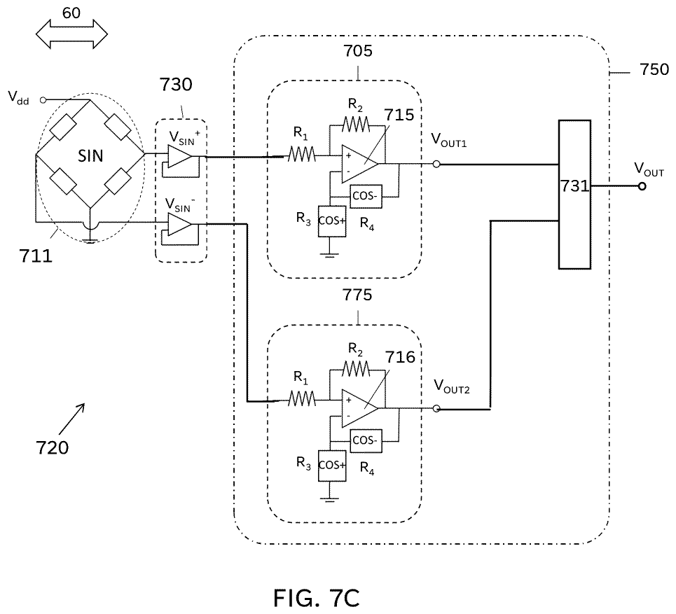

FIG. 7A shows the magnetic sensor device 700 according to an example embodiment having only one sine magnetic sensor 711 configured to generate a sine output voltage V_{SIN} following Eq. 2b. Note that the angular magnetic sensor device 700 can comprise more than one sine magnetic sensor 711. The angular magnetic sensor device 700 further comprises an analog circuit 705 having operational amplifier (op-amp) 715. A first resistance R₁ is connected to a non-inverting terminal of the op-amp 715 and a second resistance R₂ is connected between the non-inverting terminal of the op-amp 715 and to the output terminal of the op-amp 715ₜ forming a positive feedback loop for the op-amp 715. The inverting terminal is connected to ground through a third resistance R₃, while a fourth resistance R₄ is connected between the inverting terminal and the op-amp 715 output Vₒᵤₜ, forming a negative feedback loop of the op-amp 715. The sine magnetic sensor 711 comprises a plurality of MTJ elements arranged in a full bridge circuit, as described above.

In the illustrated configuration, each of half-branch output voltages of the sine magnetic sensor 711 (V_{SIN}⁺ and V_{SIN}⁻) are electrically connected to an amplifier buffer 730 and to a differential amplifier 731, so the sine output voltage V_{SIN}=V_{SIN}⁺−V_{SIN}⁻. Additionally, the sine output voltage V_{SIN} of the sine magnetic sensor 711 is electrically connected to the non-inverting terminal of the op-amp 715 via the first resistance R₁. The sine magnetic sensor 711 is biased by a bias voltage V_{dd}. The circuit output voltage of the analog circuit V_{out_ac} 705 corresponds to the device output voltage Vₒᵤₜ.

The analog circuit voltage output V_{out-ac} of the analog circuit can be expressed as:

$${V}_{out - ac} = \frac{{R}_{2} \cdot ( {R}_{3} + {R}_{4} )}{{R}_{2} \cdot {R}_{3} - {R}_{1} \cdot {R}_{4}} \cdot {V}_{in} , \qquad ( Eq . 9 )$$

where Vᵢₙ is an input voltage of the analog circuit 705. The input voltage Vᵢₙ can correspond to the sine output voltage V_{SIN} of the sine magnetic sensor 711 in the case of the configuration of FIG. 7A.

In an example embodiment, the third and fourth resistances R₃, R₄ comprise TMR elements having a resistance that follows a response with respect to the orientation of the external magnetic field as described below:

$${R}_{3} = \frac{1}{{G}_{0} \cdot ( 1 - A \cdot cos θ )} , \qquad ( Eq . 10 c )$$

$${R}_{4} = \frac{1}{{G}_{0} \cdot ( 1 + A \cdot cos θ )} . \qquad ( Eq . 10 d )$$

where G₀ is the average conductance of elements R₃ and R₄ between the parallel and antiparallel configuration of the MTJ elements.

Note that equations 10c and 10d imply that, generally, the resistance of such TMR elements does not follow a cosine response. It is understood that only for TMR elements with a relatively small TMR ratio (and therefore small amplitude A, i.e. A<<1), the resistance of such TMR elements will show a cosine response. Therefore, for the sake of clarity, the resistance response described by Eq. 10c will be defined as a cos+ response, while the resistance response described by Eq. 10d will be defined as cos− response. At such conditions, the analog circuit output voltage response V_{out-ac} of equation 9 then becomes:

$${V}_{out - ac} = 2 \cdot \frac{{R}_{2}}{{R}_{2} + {R}_{1}} \cdot ( \frac{1}{A \cdot cos θ + ( \frac{{R}_{2} - {R}_{1}}{{R}_{2} + {R}_{1}} )} ) \cdot {V}_{in} . \qquad ( Eq . 10 e )$$

Therefore, if the input voltage Vᵢₙ of the analog circuit 705 is a sine output voltage V_{SIN} generated by the sine magnetic sensor 711 (as shown in FIG. 7), then, the output voltage Vₒᵤₜ of the magnetic sensor device 700 will follow Eq. 10f:

$${V}_{out} = 2 \cdot \frac{{R}_{2}}{{R}_{2} + {R}_{1}} \cdot \frac{{V}_{SIN}}{[ ( \frac{{R}_{2} - {R}_{1}}{{R}_{2} + {R}_{1}} ) + {V}_{COS} ]} = 2 \cdot \frac{{R}_{2}}{{R}_{2} + {R}_{1}} \cdot \frac{A \cdot sin θ}{[ ( \frac{{R}_{2} - {R}_{1}}{{R}_{2} + {R}_{1}} ) + A \cdot cos θ ]} \cdot {V}_{dd} \qquad ( Eq . 10 f )$$

By defining parameter C as a parameter related to resistance values of first and second resistance elements R₁ and R₂:

$$C = \frac{{R}_{2} - {R}_{1}}{{R}_{2} + {R}_{1}} . \qquad ( Eq . 10 g )$$

The output voltage Vₒᵤₜ of magnetic sensor device 700 is proportional to Eq. 4a & 6b.

In example embodiments, the first and second resistance elements R₁ and R₂ are related to the amplitude A of TMR elements by:

$$\frac{{R}_{2} - {R}_{1}}{{R}_{2} + {R}_{1}} = β \cdot A = C \\ \qquad ( Eq . 10 h )$$

Therefore, if β=C/A~1.7 the device output voltage Vₒᵤₜ of the magnetic sensor device 700 varies linearly with respect to the angle θ of the external magnetic field 60 with a linearity error smaller than about 0.15% when the angle of the external magnetic field 60 is varied between-90° and 90° and an AE of about 0.26° as shown in FIGS. 6A-C.

Note that the sine magnetic sensor 711 can also be connected in cascade at the output of the analog circuit 705 leading to the same output voltage Vₒᵤₜ of the magnetic sensor device expressed by Eq. 10f.

Note, also, that a similar outcome can be obtained by opposite programming conditions of the tunnel magnetoresistive (TMR) elements. Indeed if:

$${R}_{3} = \frac{1}{{G}_{0} \cdot ( 1 + A \cdot cos θ )} \qquad ( Eq . 10 i )$$

$${R}_{4} = \frac{1}{{G}_{0} \cdot ( 1 - A \cdot cos θ )} , \qquad ( Eq . 10 j )$$

And by permuting the values of the first and second resistance R₁ and R₂ with respect to FIG. 7A, the analog circuit output voltage response V_{out-ac} of equation 9 then becomes:

$${V}_{out - ac} = - 2 \cdot \frac{{R}_{1}}{{R}_{2} + {R}_{1}} \cdot ( \frac{1}{A \cdot cos θ + ( \frac{{R}_{2} - {R}_{1}}{{R}_{2} + {R}_{1}} )} ) \cdot {V}_{ln} . \qquad ( Eq . 10 k )$$

In these conditions, the device output voltage Vₒᵤₜ of the magnetic sensor device can be expressed by equation 101:

$${V}_{out} = - 2 \cdot \frac{{R}_{1}}{{R}_{2} + {R}_{1}} \cdot \frac{{V}_{SIN}}{[ ( \frac{{R}_{2} - {R}_{1}}{{R}_{2} + {R}_{1}} ) + {V}_{COS} ]} = - 2 \cdot \frac{{R}_{1}}{{R}_{2} + {R}_{1}} \cdot \frac{A \cdot sin θ}{[ ( \frac{{R}_{2} - {R}_{1}}{{R}_{2} + {R}_{1}} ) + A \cdot cos θ ]} \cdot {V}_{dd} \qquad ( Eq . 10 l$$

By considering parameter C defined by Eq. 10g, the output voltage Vₒᵤₜ of this magnetic sensor device is proportional to Eq. 4a & 6b.

FIG. 7B shows the addition to FIG. 7A of a complementary analog circuit 755 also receiving the sine output voltage V_{SIN}. In this complementary analog circuit 755, resistance elements R₁ and R₂ are reversed with respect to analog circuit 705, as shown in FIG. 7B, as well as cos− and cos+ TMR elements, resulting in a simplified output voltage Vₒᵤₜ:

$${V}_{out} = \frac{2}{[ ( \frac{{R}_{2} - {R}_{1}}{{R}_{2} + {R}_{1}} ) + {V}_{COS} ]} \cdot {V}_{SIN} = 2 \cdot \frac{A \cdot sin θ}{[ ( \frac{{R}_{2} - {R}_{1}}{{R}_{2} + {R}_{1}} ) + A \cdot cos θ ]} \cdot {V}_{dd} \qquad ( Eq . 11 )$$

By considering parameter C defined by Eq. 10g, the output voltage Vₒᵤₜ of this magnetic sensor device is proportional to Eq. 4a & 6b.

In this alternative embodiment, an additional differential amplifier 731 is connected to the output of both analog circuits 705 and 755, so the output of the additional differential amplifier 731 corresponds to the output voltage Vₒᵤₜ of the magnetic sensor device 710.

In an alternative configuration of the angular magnetic sensor device 710, both analog circuits 705 and 755 are biased by a bias voltage V_{dd}. The output of both analog circuits 705 and 755 are connected to the additional differential amplifier 731, so the output of the additional differential amplifier 731 is used to bias the sine magnetic sensor 711. Here, the differential output voltage of the sine magnetic sensor 711 corresponds to the output voltage Vₒᵤₜ of the magnetic sensor device 710 and described by Eq. 11.

FIG. 7C show the addition to FIG. 7A of an equivalent circuit 775 that receives V_{SIN}⁻ from amplifier buffer 730 while circuit 705 receives V_{SIN}⁺ generating output voltage:

$${V}_{out} = {V}_{out 1} - {V}_{out 2} = \frac{R \text{?}}{R \text{?} + R \text{?}} \cdot \frac{2}{[ ( \frac{R \text{?} - R \text{?}}{R \text{?} + R \text{?}} ) + {V}_{COS} ]} \cdot {V}_{SIN} \qquad ( Eq . 12 )$$

$$\text{?} \text{indicates text missing or illegible when filed}$$

and therefore proportional to Eq. 4a & 6b.

In this alternative embodiment, each analog circuit 705 and 775 is connected to each differential output voltage of the sin full-bridge magnetic sensor 711 through the amplifier buffer 730. A differential amplifier 731 is connected to the output of both analog circuits 705 and 775, so the output of the differential amplifier 731 corresponds to the output voltage Vₒᵤₜ of the magnetic sensor device 720.

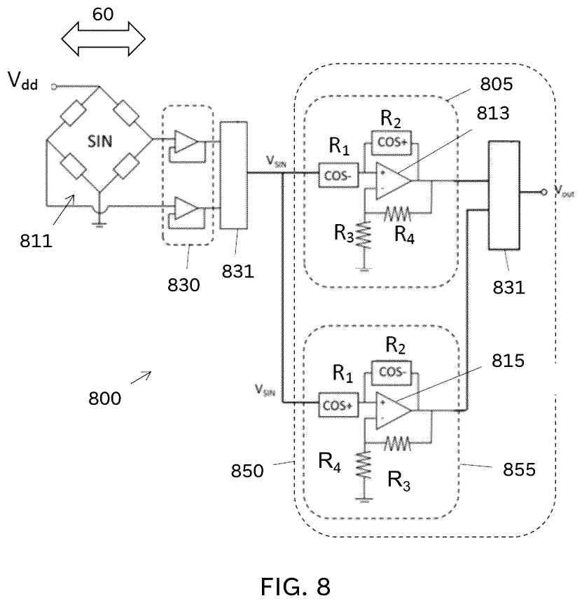

FIG. 8 shows a further alternative embodiment of an angular magnetic field sensor 800 similar to FIG. 7B but with analog circuits 805 and 855. Analog circuit 805 has an operational amplifier (op-amp) 813. A first resistance R₁ connected to a non-inverting terminal of the op-amp 813 and a second resistance R₂ connected between the non-inverting terminal of the op-amp 813 and to the output terminal of the op-amp 813ₜ forming a positive feedback loop for the op-amp 813. The inverting terminal is connected to ground through a third resistance R₃, while a fourth resistance R₄ is connected between the inverting terminal and the op-amp 813 output Vₒᵤₜ, forming a negative feedback loop of the op-amp 813. The first and second resistances R₁, R₂ comprise TMR elements having a resistance that follows a cos− and cos+ response, respectively. Alternatively, analog circuit 855 is a complementary analog circuit where resistance elements R₃ and R₄ are reversed with respect to analog circuit 805, as well as cos− and cos+ TMR elements. Both circuits receive V_{SIN} from buffer differential amplifier 831 to generate an output voltage of:

$${V}_{out} = \frac{2}{[ ( \frac{{R}_{3} - {R}_{4}}{{R}_{3} + {R}_{4}} ) + {V}_{COS} ]} \cdot {V}_{SIN} = 2 \cdot \frac{A \cdot sin θ}{[ ( \frac{{R}_{3} - {R}_{4}}{{R}_{3} + {R}_{4}} ) + A \cdot cos θ ]} \cdot {V}_{dd} \qquad ( Eq . 13 )$$

By considering parameter C defined by:

$$C = \frac{{R}_{3} - {R}_{4}}{{R}_{3} + {R}_{4}} \qquad ( Eq . 14 a )$$

the output voltage Vₒᵤₜ of this magnetic sensor device 800 is proportional to Eq. 4a & 6b.

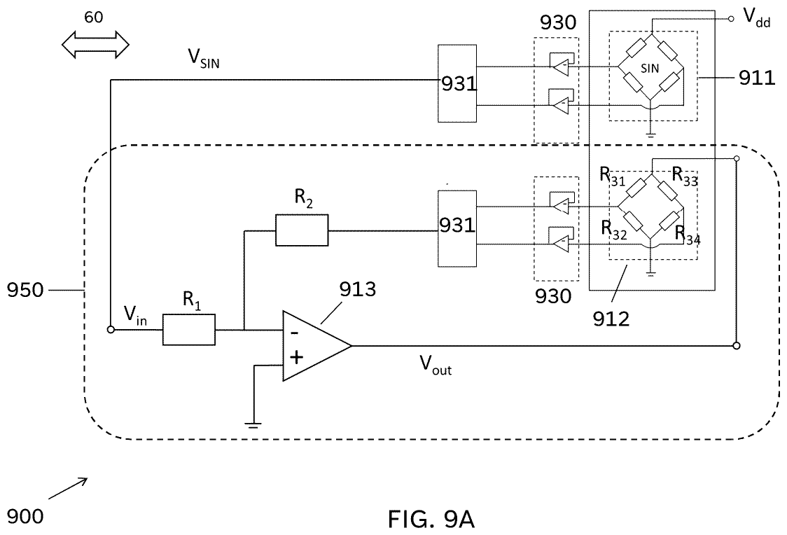

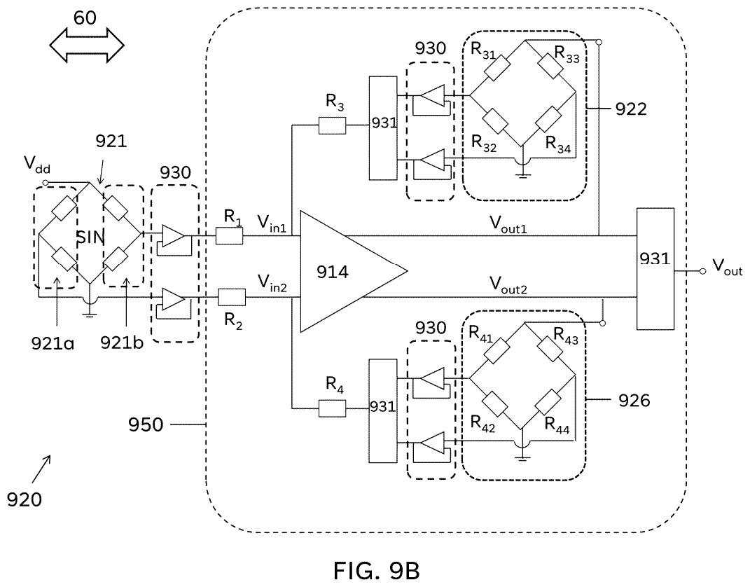

FIG. 9A shows a more general example of a magnetic field sensor device 900 similar to circuit of FIG. 3 but without the offsetting circuit and the cosine full-bridge magnetic sensor. In the illustrated configuration, a full-bridge magnetic sensor 912, with resistance elements R₃₁, R₃₂, R₃₃, R₃₄ is connected to the feedback loop of an inverting operational amplifier circuit 933.

The analog inverting operational amplifier circuit 933 comprises of an operational amplifier 913, a first resistance R₁ and a second resistance R₂ where the output voltage of the op-amp 913 is used to bias the full-bridge magnetic sensor 912. The output voltage of the op-amp 913 is generating the output voltage of the magnetic sensor device 900. Both half-bridges of the magnetic sensor 912 are electrically connected to an amplifier buffer 930 and to a differential amplifier 931. The output terminal of the differential amplifier 931 is connected to the inverting input terminal of the op-amp 913 through the second resistance R₂ to provide a feedback loop of the inverting op-amp 913. The non-inverting terminal of the op-amp 913 is connected to the ground.

The sine output voltage V_{SIN} generated by the sine full-bridge magnetic sensor 911 is outputted by the differential amplifier 931 and connected to the inverting input terminal of the op-amp 913 through the first resistance R₁.

As a consequence of this configuration the output voltage of the magnetic field sensor 900 will be:

$${V}_{out} = - \frac{{R}_{2}}{{R}_{1}} \frac{1}{[ \frac{{R}_{32}}{{R}_{31} + {R}_{32}} - \frac{{R}_{34}}{{R}_{33} + {R}_{34}} ]} \cdot {V}_{SIN} \qquad ( Eq . 15 a )$$

In a particular embodiment resistances R₃₁, R₃₂ of magnetic sensor 912 comprises TMR elements having a resistance that follows a cos+ response & cos− response respectively with respect to the orientation of the external magnetic field as described above and defined below:

$${R}_{31} = \frac{1}{{G}_{0} \cdot ( 1 - A \cdot cos θ )} ,$$

$${R}_{32} = \frac{1}{{G}_{0} \cdot ( 1 + A \cdot cos θ )} .$$

At such conditions, the output voltage of the magnetic sensor device 900 would be described as:

$${V}_{out} = \frac{{R}_{2}}{{R}_{1}} \frac{2}{[ ( \frac{{R}_{34} - {R}_{33}}{{R}_{33} + {R}_{34}} ) + {V}_{COS} ]} \cdot {V}_{SIN} = 2 \cdot \frac{{R}_{2}}{{R}_{1}} \frac{A \cdot sin θ}{[ ( \frac{{R}_{33} - {R}_{34}}{{R}_{33} + {R}_{34}} ) + A \cdot cos θ ]} \cdot {V}_{dd} \qquad ( Eq . 15 b )$$

By considering parameter C defined by:

$$C = \frac{{R}_{34} - {R}_{33}}{{R}_{33} + {R}_{34}} \qquad ( Eq . 15 c )$$

the output voltage Vₒᵤₜ of this magnetic sensor device 900 is proportional to Eq. 4a & 6b.

In an alternative embodiment, TMR elements R₃₁, R₃₂ show cos− and cos+ response respectively with respect to the orientation of the external magnetic field:

$${R}_{31} = \frac{1}{{G}_{0} \cdot ( 1 + A \cdot cos θ )} ,$$

$${R}_{32} = \frac{1}{{G}_{0} \cdot ( 1 - A \cdot cos θ )} .$$

which produces an output voltage of the magnetic sensor device 900 described as:

$${V}_{out} = - \frac{{R}_{2}}{{R}_{1}} \frac{2}{[ ( \frac{{R}_{33} - {R}_{34}}{{R}_{33} + {R}_{34}} ) + {V}_{COS} ]} \cdot {V}_{SIN} = - 2 \cdot \frac{{R}_{2}}{{R}_{1}} \frac{A \cdot sin θ}{[ ( \frac{{R}_{33} - {R}_{34}}{{R}_{33} + {R}_{34}} ) + A \cdot cos θ ]} \cdot {V}_{dd} \qquad ( Eq . 15 d )$$

By considering parameter C defined by:

$$C = \frac{{R}_{33} - {R}_{34}}{{R}_{33} + {R}_{34}} \qquad ( Eq . 15 e )$$

the output voltage Vₒᵤₜ of this magnetic sensor device 900 is proportional to Eq. 4a & 6b.

FIG. 9B shows a further alternative embodiment of an angular magnetic field. The magnetic sensor device 920 is similar to circuit of FIG. 9A but with an additional complementary full-bridge magnetic sensor and a fully differential operational amplifier op-amp. Magnetic sensor device 920 comprises a full-bridge sine magnetic sensor 921 configured to provide a sine output voltage V_{SIN} and biased by the bias voltage V_{dd}. The angular magnetic sensor device 920 further comprises a full-bridge magnetic sensor 922.

The angular magnetic sensor device 920 further comprises an analog circuit 950 including a fully differential op-amp 924, a first, second, third and fourth resistance R₁, R₂, R₃, R₄, a full-bridge magnetic sensor 922 and an additional full-bridge magnetic sensor 926. The full-bridge magnetic sensor 922 comprises elements R₃₁, R₃₂, R₃₃, R₃₄ and the full-bridge magnetic sensor 926 comprises elements R₄₁, R₄₂, R₄₃, R₄₄. A first half branch 921a of the full-bridge sine magnetic sensor 921 is connected to a first input voltage Vᵢₙ of the fully differential op-amp 924 through the first resistance R₁ and the amplifier buffer 930. A second half branch 921b of the of the full bridge sine magnetic sensor 921 is connected to a second input voltage Vᵢₙ₂ of the fully differential op-amp 924 through the second resistance R₂ and the amplifier buffer 930. A first circuit output voltage Vₒᵤₜ₁ of the fully differential op-amp 924 biases the full-bridge magnetic sensor 922 and a second circuit output voltage Vₒᵤₜ₂ of the fully differential op-amp 924 biases the second full-bridge magnetic sensor 926. The output of the full-bridge magnetic sensor 922 is electrically connected to the first input terminal of the fully differential op-amp 924 through the third resistance R₃. The output of the additional full-bridge magnetic sensor 926 is electrically connected to the second input terminal of the fully differential op-amp 924 through the fourth resistance R₄.

In one aspect, the output of each of the full-bridge magnetic sensors 922 and 926 can be further electrically connected to an amplifier buffer 930 (voltage follower) and to a differential amplifier 931.

In this configuration, the output voltage of the full-bridge magnetic sensor 922 V_{out_12} can be described as:

$${V}_{out \_ 12} = [ \frac{{R}_{32}}{{R}_{31} + {R}_{32}} - \frac{{R}_{34}}{{R}_{33} + {R}_{34}} ] \cdot {V}_{out \_ 1} , \qquad ( Eq . 16 a )$$

and the output voltage of the full-bridge magnetic sensor 926 V_{out_22} can be described as:

$${V}_{out \_ 22} = [ \frac{{R}_{42}}{{R}_{41} + {R}_{42}} - \frac{{R}_{44}}{{R}_{43} + {R}_{44}} ] \cdot {V}_{out \_ 2} . \qquad ( Eq . 16 b )$$

In a particular embodiment resistances R₃₁, R₃₂ of magnetic sensor 922 comprise TMR elements having a resistance that follows a cos+ response & cos− response respectively with respect to the orientation of the external magnetic field and resistance R₄₁, R₄₂ of magnetic sensor 926 comprises TMR elements having a resistance that follows a cos+ response & cos− response respectively with respect to the orientation of the external magnetic field:

$${R}_{31} = \frac{1}{{G}_{0} \cdot ( 1 - A \cdot cos θ )} ,$$

$${R}_{32} = \frac{1}{{G}_{0} \cdot ( 1 + A \cdot cos θ )} .$$

$${R}_{41} = \frac{1}{{G}_{0} \cdot ( 1 - A \cdot cos θ )} ,$$

$${R}_{32} = \frac{1}{{G}_{0} \cdot ( 1 + A \cdot cos θ )} .$$

In this configuration the output voltage Vₒᵤₜ of the angular magnetic sensor device 920 corresponds to the voltage difference between the first circuit output voltage Vₒᵤₜ₁ and the second circuit output voltage Vₒᵤₜ₂ and described by:

$${V}_{out} = {V}_{out 1} - {V}_{out 2} = [ \frac{{R}_{2}}{{R}_{1}} \frac{( 1 + A \cdot sin θ )}{[ ( \frac{{R}_{34} - {R}_{33}}{{R}_{33} + {R}_{34}} ) + A \cdot cos θ ]} ] \cdot {V}_{d d} - [ \frac{{R}_{2}}{{R}_{1}} \frac{( 1 - A \cdot sin θ )}{[ ( \frac{{R}_{34} - {R}_{33}}{{R}_{33} + {R}_{34}} ) + A \cdot cos θ ]} ] \cdot {V}_{d d} \qquad ( Eq . 16 c )$$

$$or :$$

$${V}_{out} = 2 \cdot \frac{{R}_{2}}{{R}_{1}} \frac{A \cdot sin θ}{[ ( \frac{{R}_{34} - {R}_{33}}{{R}_{33} + {R}_{34}} ) + A \cdot cos θ ]} \cdot {V}_{d d} \qquad ( Eq . 16 d )$$

By considering parameter C defined by Eq. 15c, the output voltage Vₒᵤₜ of this magnetic sensor device 920 is proportional to Eq. 4a and 6b.

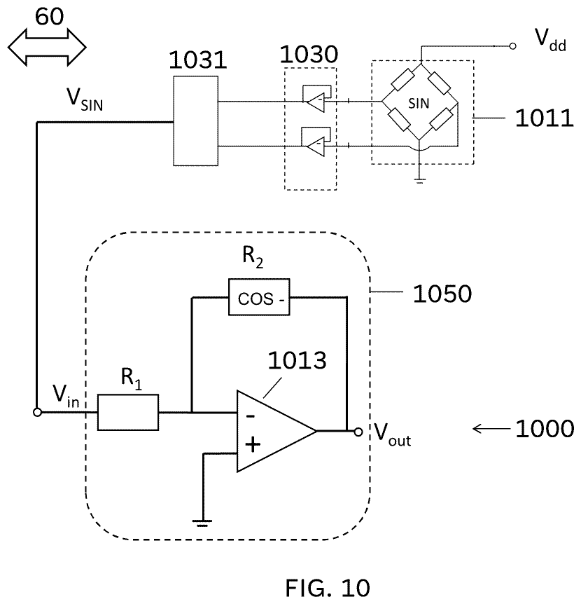

FIG. 10 shows the circuit of an alternative embodiment of an angular magnetic sensor device 1000 comprising a sine full-bridge magnetic sensor 1011, a TMR element R₂ following a cos− response with respect to the orientation of the external magnetic field:

$${R}_{2} = \frac{1}{{G}_{0} \cdot ( 1 + A \cdot cos θ )}$$

and an inverting operational amplifier 1013, where R₂ is connected to the inverting terminal of the op-amp 1013 and the output terminal of the op-amp 1013 in a feedback loop and where the output voltage of the op-amp 1013 corresponds to the output voltage of the magnetic sensor device 1000.

The sine full-bridge magnetic sensor 1011 is configured to generate a differential output voltage that is a sine output voltage V_{SIN} and is proportional to its bias voltage V_{dd} (as described by Eq. 1b). The sine output voltage V_{SIN} follows a sine function with respect to the external magnetic field orientation. Both half-branch output voltages of the sine full-bridge magnetic sensor 1011 are electrically connected to an amplifier buffer 1030 and to a differential amplifier 1031. The sine output voltage V_{SIN} generated by the differential amplifier 1031 is also connected to the inverting input terminal of the op-amp 1013 through the first resistance R₁. The non-inverting terminal of the op-amp 1013 is connected to the ground in the illustrated embodiment.

As a consequence of this configuration, the output voltage of the magnetic sensor device 1000 Vₒᵤₜ can be expressed as:

$${V}_{out} = - \frac{{R}_{2}}{{R}_{1}} \cdot {V}_{SIN} \\ \text{?} \qquad ( Eq . 17 a )$$

$${V}_{out} = - \frac{1}{{R}_{1}} \cdot \frac{A \cdot sin θ}{{G}_{0} \cdot ( 1 + A \cdot cos θ )} \cdot {V}_{dd} \qquad ( Eq . 17 b )$$

$$\text{?} \text{indicates text missing or illegible when filed}$$

Note that in this case, by comparison with Eq. 4a and 6b, C=1.

As the amplitude A of sine and cosine signals generated by the TMR elements are related to the TMR ratio by:

$$A = ( \frac{TMR}{TMR + 2} )$$

This implies that optimum C/A ratios for a linear output response of the angular magnetic field sensor device 1000 at certain angle ranges (as described by FIG. 5C) can be obtained for TMR elements with TMR ratios >120%.

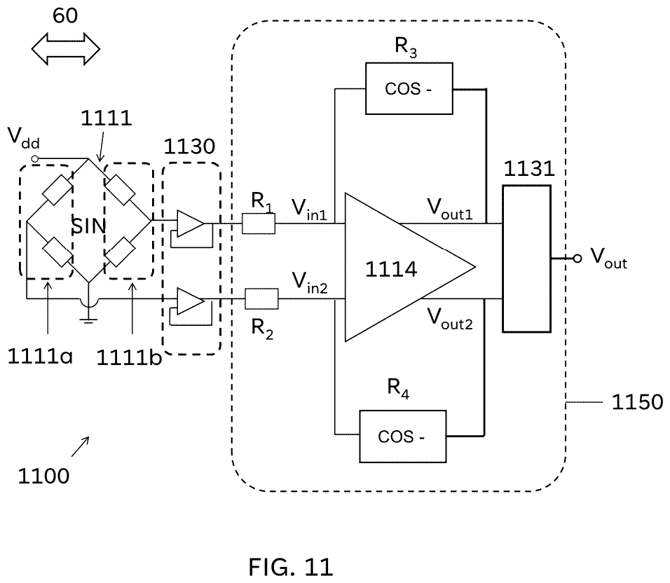

FIG. 11 shows a further alternative embodiment of an angular magnetic field device 1100 comprising a sine full-bridge magnetic sensor 1111 configured to provide a sine output voltage V_{SIN} and inputted by the bias voltage V_{dd}, two TMR elements R₃ and R₄ following a cos− response with respect to the orientation of the external magnetic field:

$${R}_{3} = {R}_{4} = \frac{1}{{G}_{0} \cdot ( 1 + A \cdot cos θ )}$$

and a fully differential operational amplifier 1114, where R₃ is connected between the first output voltage Vₒᵤₜ₁ of the fully differential operational amplifier 1114 and the first input voltage terminal Vᵢₙ₁ of the fully differential operational amplifier 1114 and wherein R₄ is connected between the second output voltage Vₒᵤₜ₂ of the fully differential operational amplifier 1114 and the second input voltage terminal Vᵢₙ₂ of the fully differential operational amplifier 1114. A first half branch 1111a of the full-bridge sine magnetic sensor 1111 is connected to the first input voltage Vᵢₙ₁ of the fully differential op-amp 1114 through a first additional resistance R₁ and the amplifier buffer 1130. A second half branch 1111b of the of the full bridge sine magnetic sensor 1111 is connected to a second input voltage Vᵢₙ₂ of the fully differential op-amp 1114 through a second additional resistance R₂ and the amplifier buffer 1130.

In this configuration the output voltage Vₒᵤₜ of the angular magnetic sensor device 1100 corresponds to the voltage difference between the first output voltage Vₒᵤₜ₁ of the fully differential operational amplifier 1114 and the second output voltage Vₒᵤₜ₂ of the fully differential operational amplifier 1114 and described by:

$${V}_{out} = {V}_{out 1} - {V}_{out 2} = \frac{1}{2} \cdot \frac{1}{{R}_{1}} \cdot [ \frac{1 + A \cdot sin θ}{{G}_{0} \cdot ( 1 + A \cdot cos θ )} ] \cdot {V}_{dd} - \frac{1}{2} \cdot \frac{1}{{R}_{2}} \cdot [ \frac{1 - A \cdot sin θ}{{G}_{0} \cdot ( 1 + A \cdot cos θ )} ] \cdot {V}_{d d} . \qquad ( Eq . 18 a )$$

In some embodiments, R₁=R₂ and then:

$${V}_{out} = \frac{1}{2} \cdot \frac{1}{{R}_{1}} \cdot [ \frac{( 1 + A \cdot sin θ ) - ( 1 - A \cdot sin θ )}{{G}_{0} \cdot ( 1 + A \cdot cos θ )} ] \cdot {V}_{dd} = \frac{1}{{R}_{1}} \cdot [ \frac{A \cdot sin θ}{{G}_{0} \cdot ( 1 + A \cdot cos θ )} ] \cdot {V}_{d d} . \qquad ( Eq . 18 b )$$

Note that in this case, by comparison with Eq. 4a and 6b, C=1.

In a particular embodiment, the TMR elements of this angular magnetic field sensor device 1100 have TMR ratios >120%.

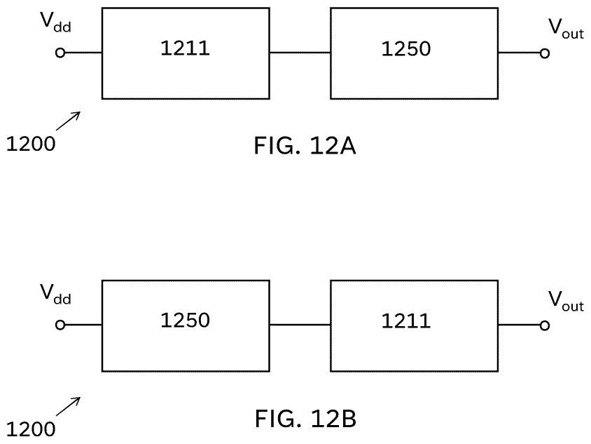

FIGS. 12A and 12B show generalized block diagrams of respective angular magnetic sensor devices generating an output voltage response proportional to Eq. 4a and able to provide a linear output voltage with respect to the orientation of the external magnetic field θ. The angular magnetic sensor device 1200 is configured by at least: a) a sine magnetic sensor 1211, comprising a plurality of tunnel magnetoresistance (TMR) elements, arranged in a full-bridge configuration and configured to provide an output voltage proportional to a sine function with respect to the orientation of the external magnetic field θ as well as to its input bias voltage and b) an analog circuit 1250, comprising at least a tunnel magnetoresistance (TMR) element, configured to generate a circuit output voltage V_{out_ac} depending on the orientation of the external magnetics field θ:

$${V}_{out \_ ac} = \frac{1}{( C + A \cdot cos θ )} \cdot {V}_{in \_ ac} \qquad ( Eq . 19 )$$

where C is an offset voltage generated by the analog circuit 1250 and V_{in_ac} is the input voltage of the analog circuit 1250. Note that the sine magnetic sensor 1211 may comprise voltage buffers and a differential amplifier.

Both components 1211 and 1250 of the angular magnetic sensor device can be arranged so the sine magnetic sensor 1211 is biased by a bias voltage V_{dd} and the analog circuit 1250 is biased by the output voltage of the sine magnetic sensors 1211 (FIG. 12A) or the analog circuit 1250 is biased by a bias voltage V_{dd} and the sine magnetic sensor 1211 is biased by the output voltage of the analog circuit 1250 (FIG. 12B).

In both cases the output voltage of the angular magnetic sensor device will follow Eq. 4a or 6b.

Basic components 1211 and 1250 can be combined to form additional angular magnetic sensor devices generating an output voltage proportional to Eq. 4b or 4c and able to provide a linear output voltage with respect to the orientation of the external magnetic field θ.

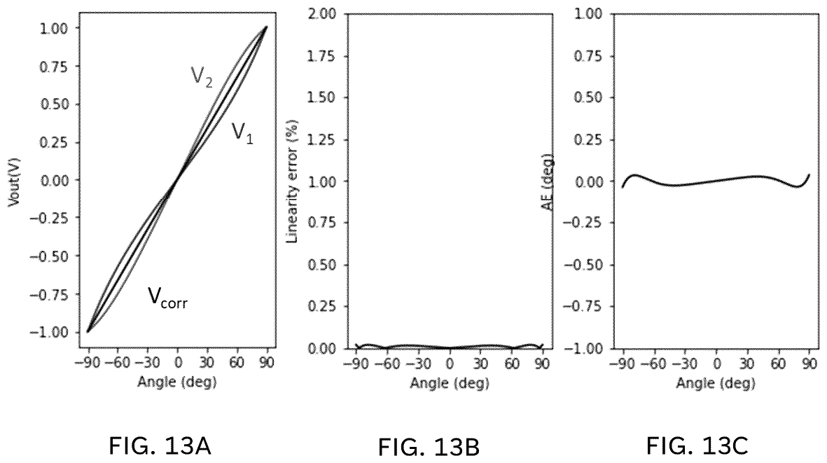

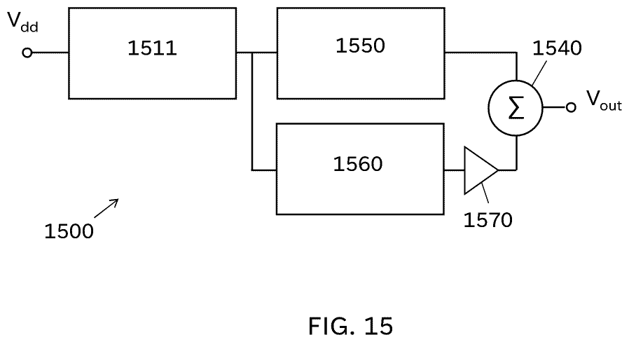

FIGS. 13A-C show responses of a sensor device in accordance with example embodiments of the disclosure. FIG. 13A shows the output voltage response Vₒᵤₜ of an angular magnetic field sensor device 1500 described by FIG. 15 for a ratio C₁/A of about 1 for the first analog circuit 1550, a ratio C₂/A of about 3.42 and a gain k~3.42. At such conditions, the device output voltage Vₒᵤₜ varies linearly with respect to the angle θ of the external magnetic field 60 when the angle of the external magnetic field 60 is varied between −90° and 90° as shown in FIG. 13A with a linearity error smaller than about 0.03%, as shown in FIG. 13B, and an AE of <0.04° is obtained as shown in FIG. 13C.

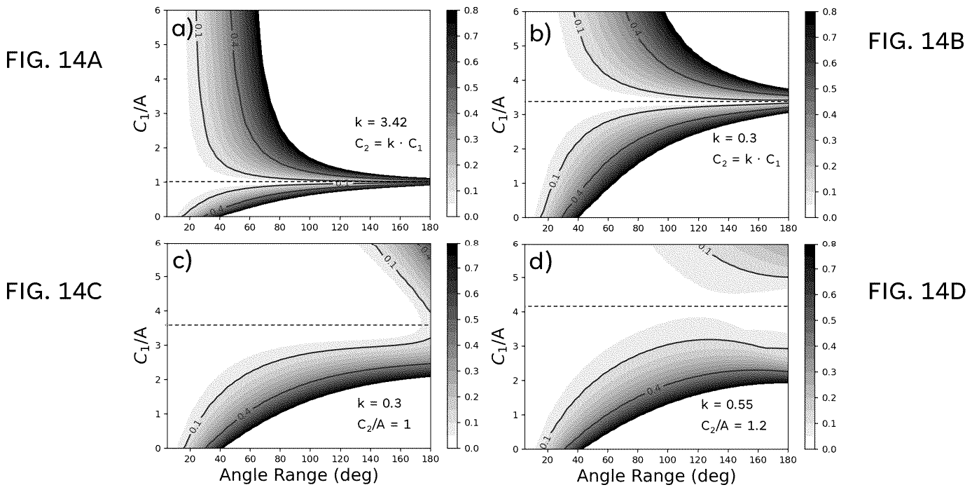

FIGS. 14A-D show different examples of optimum conditions of C₁/A ratio, C₂/A ratio and k parameter for linearity errors <0.1%. Note the conditions reflected in FIGS. 14C and 14D with large areas of different C₁/A ratios for angle ranges up to 180° can be achieved.

FIG. 15 shows an angular magnetic field sensor device 1500 generating an output voltage described by Eq. 4b. The angular magnetic sensor device 1500 includes: a) at least a sine magnetic sensor 1511, comprising a plurality of tunnel magnetoresistance (TMR) elements, arranged in a full-bridge configuration and configured to provide an output voltage proportional to a sine function with respect to the orientation of the external magnetic field e as well as to its input bias voltage and b) a first analog circuit 1550, comprising at least a tunnel magnetoresistance (TMR) element, configured to generate a circuit output voltage V_{out_ac} described by Eq. 19, c) a second analog circuit 1560, comprising at least a tunnel magnetoresistance (TMR) element, configured to generate a circuit output voltage V_{out_ac} described by Eq. 19, wherein the C₂ offset voltage generated by the second analog circuit 1560 is different than the C₁ offset voltage generated by the first analog circuit 1550, d) a gain amplifier 1570 providing a k amplification of the output voltage of the second analog circuit 1560 and e.) a summing amplifier 1540.

In some embodiments a differential amplifier instead of a summing amplifier can be considered.

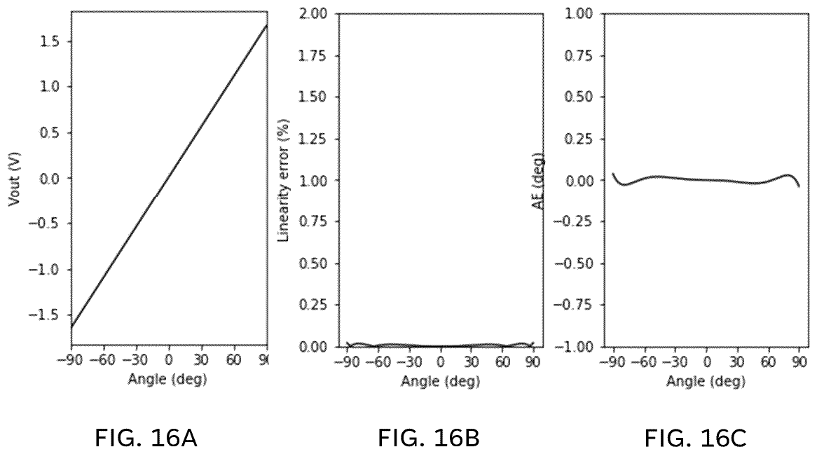

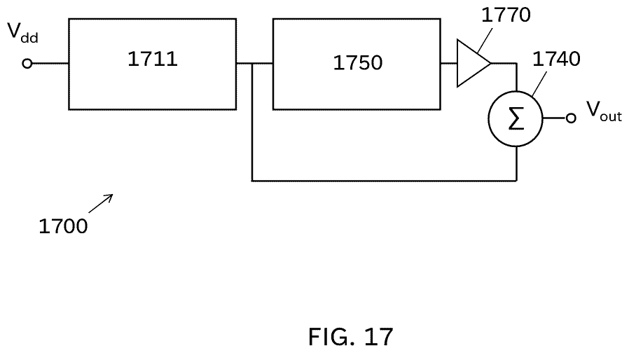

FIGS. 16A-C show the output voltage response Vₒᵤₜ of an angular magnetic field sensor device 1700 described by FIG. 17 for a ratio C₁/A of about 1.4 for the first analog circuit 1750, and a gain K~8.63×A. At such conditions, the device output voltage Vₒᵤₜ varies linearly with respect to the angle θ of the external magnetic field 60 when the angle of the external magnetic field 60 is varied between −90° and 90° as shown in FIG. 16A with a linearity error smaller than about 0.03%, as shown in FIG. 16B, and an AE of <0.04° is obtained as shown in FIG. 16C.

FIG. 17 shows an angular magnetic field sensor device 1700 generating an output voltage described by Eq. 4c. The angular magnetic sensor device 1700 comprises: a) at least a sine magnetic sensor 1711, comprising a plurality of tunnel magnetoresistance (TMR) elements, arranged in a full-bridge configuration and configured to provide an output voltage proportional to a sine function with respect to the orientation of the external magnetic field θ as well as to its input bias voltage and b) an analog circuit 1750, comprising at least a tunnel magnetoresistance (TMR) element, configured to generate a circuit output voltage V_{out_ac} described by Eq. 19, d) a gain amplifier 1770 providing a K amplification of the output voltage of the analog circuit 1750 and e.) a summing amplifier 1740. In some embodiments a differential amplifier instead of a summing amplifier can also be considered.

Having described exemplary embodiments of the disclosure, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. An angular magnetic field sensor device for measuring the orientation of an external magnetic field, comprising:
at least a sine magnetic sensor, comprising a plurality of tunnel magnetoresistance (TMR) elements, arranged in a full-bridge configuration and configured to provide a sine output voltage V_{SIN} defined as V_{SIN}=A·sin θ·V_{dd},
where A is the amplitude parameter depending on a TMR ratio of the TMR elements, Vdd is an input voltage of the magnetic sensor and θ is an orientation of the external magnetic field;
an analog circuit comprising at least one AC tunnel magnetoresistance (TMR) element configured to generate a circuit output voltage V_{out_ac} depending on the orientation of the external magnetics field θ.

2. The device according to claim 1, wherein the circuit output voltage V_{out_ac} is defined as:
$${V}_{out \_ ac} = \frac{1}{( C + A \cdot cos θ )} \cdot {V}_{in \_ ac}$$
wherein C is an offset voltage generated by the analog circuit and V_{in_ac} is an input voltage of the analog circuit.

3. The device according to claim 2, wherein the sine magnetic sensor and the analog circuit are electrically connected so the output voltage generated by the angular magnetic field sensor device is proportional to:
$${V}_{out} = \frac{A \cdot sin θ}{( C + A \cdot cos θ )} .$$

4. The device according to claim 3, wherein 1<C/A≤2.5.

5. The device according to claim 3, wherein C/A=1.7±0.2.

6. The device according to claim 3, wherein the analog circuit is driven by the output voltage of the sine magnetic field sensor.

7. The device according to claim 3, wherein the sine magnetic field sensor is driven by the output voltage of the analog circuit.

8. The device according to claim 2, further including an additional analog circuit comprising at least one tunnel magnetoresistance (TMR) element configured to generate a circuit output voltage V_{out2_ac} depending on the orientation of the external magnetics field θ:
$${V}_{out 2 \_ ac} = \frac{1}{( {C}_{2} + A \cdot cos θ )} \cdot {V}_{in 2\_ ac}$$
wherein C₂ is an offset voltage generated by the additional analog circuit and V_{in2_ac} is the input voltage of the additional analog circuit.

9. The device according to claim 8, wherein the sine magnetic sensor is electrically connected to the analog circuit.

10. The device according to claim 8, wherein the sine magnetic sensor is electrically connected to the additional analog circuit.

11. The device according to claim 10, wherein the output voltage generated by the angular magnetic field sensor device is proportional to the addition of output voltages of the analog circuit and the additional analog circuit.

12. The device according to claim 11, further including a voltage amplifier with gain k1 coupled to an output of the analog circuit.

13. The device according to claim 11, further including a voltage amplifier with gain k2 coupled to an output of the additional analog circuit.

14. The device according to claim 13, further comprising a summing amplifier to add the output voltages of the analog circuit and the additional analog circuit.

15. The device according to claim 13, further comprising a differential amplifier to subtract the output voltages of the analog circuit and the additional analog circuit.

16. The device according to any of claim 15, wherein 1<C/A≤10 and 1<C₂/A≤10.

17. The device according to claim 2, wherein the sine magnetic sensor is electrically connected to the analog circuit of the angular magnetic field sensor device,
and wherein the output voltage generated by the angular magnetic field sensor device is proportional to the addition of the output voltage of the analog circuit and the output voltage of the sine magnetic sensor.

18. The device according to claim 17, further comprising a summing amplifier to add the output voltage of the analog circuit and the output voltage of the sine magnetic sensor.

19. The device according to claim 18, wherein the device output voltage shows a linearity error <0.5% and/or angular error <1 deg for angular magnetic field ranges up to ±90°.

20. The device according to claim 19, wherein the TMR elements show a TMR ratio >120%.
